(19) United States
(12) Patent Application Publication
(10) Pub. No.: US 2019/0098766 A1
(43) Pub. Date: Mar. 28, 2019

(54) ELECTRONIC CIRCUIT BOARD AND ULTRASONIC BONDING METHOD

(71) Applicant: HONDA MOTOR CO., LTD., Minato-ku, Tokyo (JP)

(72) Inventors: Nobuhiro Fueki, Tochigi (JP); Masaki Kunigami, Tochigi (JP); Tsugio Masuda, Tochigi (JP)

(21) Appl. No.: 16/081,979

(22) PCT Filed: Feb. 27, 2017
(86) PCT No.: PCT/JP2017/007532

§ 371 Date: Sep. 4, 2018

(30) Foreign Application Priority Data
Mar. 11, 2016 (JP) 2016-047922

(51) Int. Cl. H05K 3/10; B23K 20/10; H05K 1/03

(52) U.S. Cl. CPC H05K 3/103; B23K 2101/42; H05K 1/0313; B23K 20/10

(57) ABSTRACT

A PCB (1) has a reinforcing member (12) composed of a material having a higher melting point than a synthetic resin constituting a substrate (10). A first reinforcing member (121) constituting the reinforcing member (12) is composed of a substantially tabular or belt-shaped metal buried in the substrate (10), the metal being at least partially overlapped with an upper surface wire (11). A second reinforcing member (122) constituting the reinforcing member (12) is composed of a substantially columnar metal which is connected to the lower surface of the upper surface wire (11) and physically, chemically or mechanically connected to the first reinforcing member (121), and which vertically extends, in the same manner as a via (111).

### TECHNICAL FIELD

The present invention relates to a technology for bonding conductors to each other by ultrasonic vibration energy.

### BACKGROUND ART

There has been proposed a method for bonding a conductor coated with a synthetic resin to a conductor bonded to the upper surface of a substrate including a synthetic resin by ultrasonic vibration energy (refer to, for example, Patent Literature 1). According to the method, in a state in which an object to be bonded has been held between a horn and an anvil, a synthetic resin coating one conductor is first melted by the ultrasonic vibration energy of the horn so as to remove the synthetic resin from between the two conductors, and then the two conductors are bonded to each other.

### CITATION LIST

### Patent Literature

Patent Literature 1: Japanese Patent Application Laid-Open No. 2005-223054

### SUMMARY OF INVENTION

### Technical Problem

However, if a synthetic resin constituting a substrate or an adhesive agent locally incurs a temperature increase and softens due to the ultrasonic vibration energy, then a part of the ultrasonic vibration energy is inconveniently absorbed by the vibration on the softened synthetic resin of the conductor placed on the substrate. Hence, the efficiency of the ultrasonic vibration energy to contribute to the bonding energy at the place where the two conductors are in contact deteriorates, leading to a possibility of an insufficient bonding strength of the two conductors.

Therefore, an object of the present invention is to provide an electronic circuit board provided with a substrate, which includes a synthetic resin and which has a conductor bonded to the upper surface thereof, and an ultrasonic bonding method, the electronic circuit board and the ultrasonic bonding method enabling an improved quality of bonding of another conductor to the foregoing conductor.

### Solution to Problem

The present invention is an electronic circuit board provided with: a substrate which includes a synthetic resin; and a conductor bonded to an upper surface of the substrate, wherein a reinforcing member made of a material having a melting point that is higher than that of the substrate is bonded to a lower surface of the conductor such that the reinforcing member does not affect a conduction state between the conductor and a wiring of the electronic circuit board, and buried in the substrate or bonded to a lower surface or the upper surface of the substrate. In the electronic circuit board according to the present invention, the reinforcing member preferably includes one or a plurality of tabular first reinforcing members, which are disposed apart downward with respect to the conductor, and a second reinforcing member which vertically connects the substrate and the first reinforcing member or members.

An ultrasonic bonding method according to the present invention is a method for ultrasonically bonding another conductor to the conductor bonded to the upper surface of the electronic circuit board according to the present invention, the ultrasonic bonding method including: a step of sandwiching, by a horn vibrated by a piezoelectric element and an anvil disposed opposing the horn, the electronic circuit board and the another conductor such that an exposed place of the upper surface of the another conductor and the conductor vertically overlap; and a step of displacing the horn downward while ultrasonically vibrating the horn in a horizontal direction so as to bond the conductor, which is disposed on the electronic circuit board, and the another conductor.

### Effect of the Invention

According to the electronic circuit board in accordance with the present invention, the reinforcing members are bonded to the lower surface of the another conductor bonded to the upper surface of the electronic circuit board and buried in the substrate or bonded to the lower surface or the upper surface of the substrate. With this arrangement, even if the substrate locally incurs a temperature increase and softens due to the ultrasonic vibration energy of the horn, the vibration of the conductor bonded to the upper surface of the substrate is suppressed by the reinforcing members, thus leading to efficient contribution of the ultrasonic vibration energy to the bonding at the place of contact between the another conductor and the another conductor. Thus, the quality of bonding between the conductor bonded to the upper surface of the electronic circuit board and the another conductor is improved.

### BRIEF DESCRIPTION OF DRAWINGS

FIG. 1 is an explanatory diagram illustrating the configuration of an electronic circuit board according to an embodiment of the present invention;

FIG. 2 is a sectional view taken on line in FIG. 1;

FIG. 3 is an explanatory diagram related to an ultrasonic bonding method as an embodiment of the present invention;

FIG. 4 is an explanatory diagram of the bonding between an electronic circuit board as an embodiment of the present invention and another conductor;

FIG. 5A is an explanatory diagram related to the results of evaluation of a bonding output of the electronic circuit board of a working example;

FIG. 5B is an explanatory diagram related to the results of evaluation of a bonding output of the electronic circuit board of a comparative example; and

FIG. 6 is an explanatory diagram related to the results of evaluation of the tensile strengths of the electronic circuit board and the conductor.

### DESCRIPTION OF EMBODIMENTS

(Configuration)

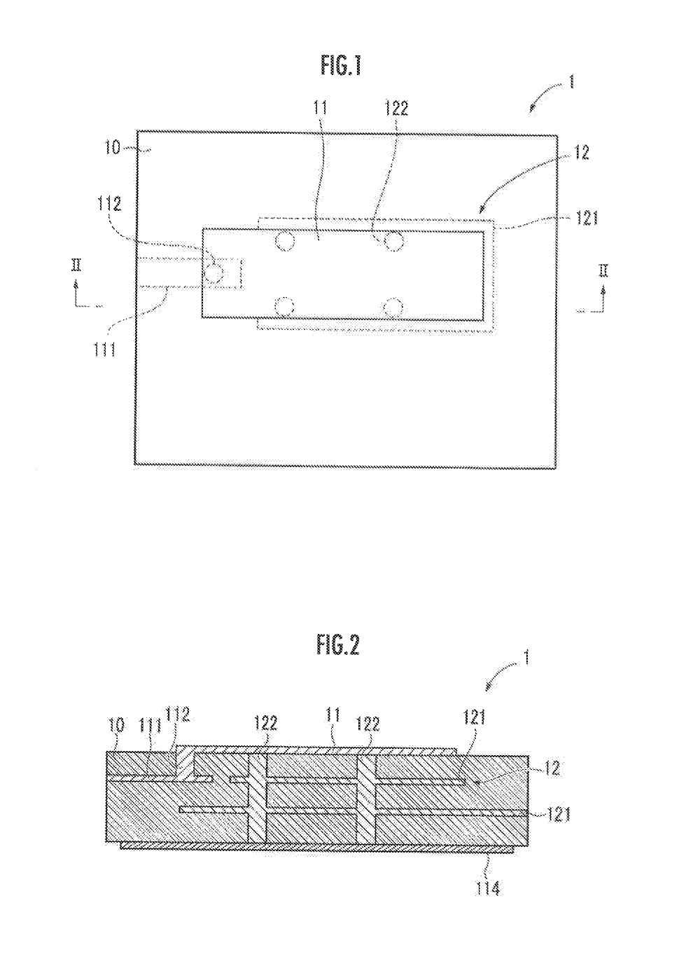

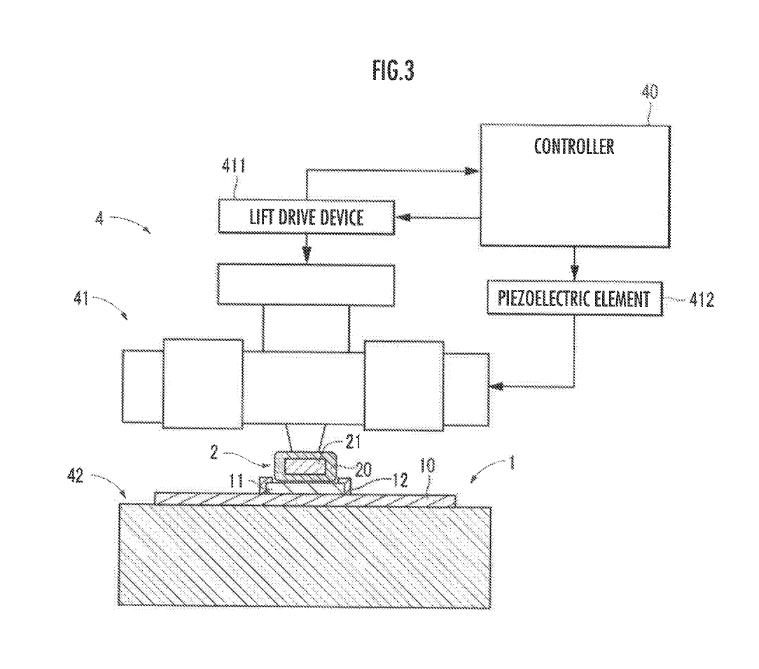

An electronic circuit board as an embodiment of the present invention illustrated in FIG. 1 and FIG. 2 is a PCB 1 (a printed circuit board or a printed wiring board), and has a substrate 10, one or a plurality of upper surface wires 11, one or a plurality of vias 111, one or a plurality of internal wires 112, and one or a plurality of lower surface wires 114.

The substrate 10 includes a synthetic resin, and is an epoxy glass substrate that contains, for example, an epoxy resin as the synthetic resin. Each of the upper surface wires 11 and the lower surface wires 114 is composed of a substantially tabular metal bonded to the upper surface and the lower surface, respectively, of the substrate 10. The upper surface wires 11 and the lower surface wires 114 may be directly bonded to the substrate 10 or indirectly bonded or attached through an adhesive agent to the substrate 10. The internal wire 112 is composed of a substantially tabular or a belt-shaped metal buried in the substrate 10, at least partially overlapping the upper surface wire 11. The via 111 is composed of a substantially columnar metal which connects the upper surface wire 11 and the internal wire 112 and which vertically extends. The metals that constitute each of the upper surface wire 11, the via 111, the internal wire 112, and the lower surface wire 114 are, for example, Cu, Al or an alloy thereof.

The PCB 1 is further provided with a reinforcing member 12 composed of a material (e.g. metal) having a higher melting point than the synthetic resin constituting the substrate 10. The reinforcing member 12 has one or a plurality of first reinforcing members 121 and one or a plurality of second reinforcing members 122. The first reinforcing member 121 is composed of a substantially tabular or a belt-shaped metal buried in the substrate 10, at least partially overlapping the upper surface wire 11. The second reinforcing member 122 is composed of a vertically extending substantially columnar metal which is connected to the lower surface of the upper surface wire 11, which is physically, chemically or mechanically connected to the first reinforcing member 121, as with the via 111. The second reinforcing members 122 are formed by a method that is the same as that for forming general vias in a printed board. In the present embodiment, the second reinforcing members 122 are arranged to connect the upper surface wire 11, the two first reinforcing members 121, which are positioned vertically apart from each other, and a lower surface wire 114.

The upper surface wire 11 and the internal wire 112 of the PCB 1 are in conduction through the vias 111, and the reinforcing member 12 is disposed such that the presence of the reinforcing member 12 does not cut off (or not affect) the conduction. According to the present embodiment, the second reinforcing members 122 are formed of vias that provide conduction between the upper surface wire 11 and the lower surface wire 114. The presence of the reinforcing member 12, which has the second reinforcing members 122 as the constituent elements thereof also does not cut off the conduction between the upper surface wire 11 and the lower surface wire 114.

(Ultrasonic Bonding Method)

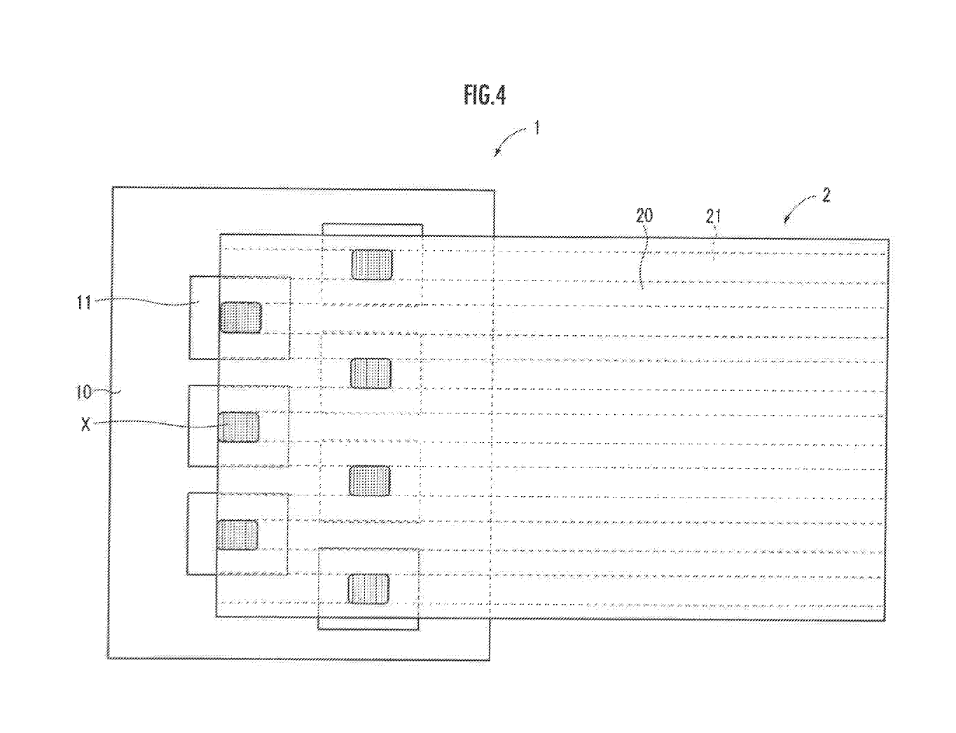

The following will describe the method for ultrasonically bonding an FFC 2 (flexible flat cable) to the PCB 1 by using an ultrasonic apparatus illustrated in FIG. 3. The FFC 2 includes a plurality of external wires 21 and an insulating cover 20 which is composed of a synthetic resin and which provides covering that electrically isolates the plurality of the external wires 21 from each other.

An ultrasonic bonding apparatus 4 includes a horn 41 (or a chip), an anvil 42 opposed to and disposed under the horn 41, a lift drive device 411 which drives the horn 41 in a vertical direction, a piezoelectric element 412 (ultrasonic vibrator), which ultrasonically vibrates the horn 41, and a controller 40. The lower end portion of the horn 41 is formed to have a substantially truncated conical shape having its upper base facing downward; however, the shape of the lower end portion can be changed as appropriate to have, for example, a plurality of projections with belt-like or dot-like distal ends, according to how the conductors to be bonded are arranged. The upper end portion of the anvil 42 is substantially flat, but may be provided with projections and recesses, as appropriate, according to the shape of the horn 41.

The controller 40 is comprised of a computer (which includes a CPU (central processing unit), a memory (storage device), such as a ROM or RAM, an I/O circuit, and the like). The central processing unit reads necessary programs and data from the storage device to carry out the arithmetic processing, such as control of the operations of the lift drive device 411 and the piezoelectric element 412 according to the programs and the data.

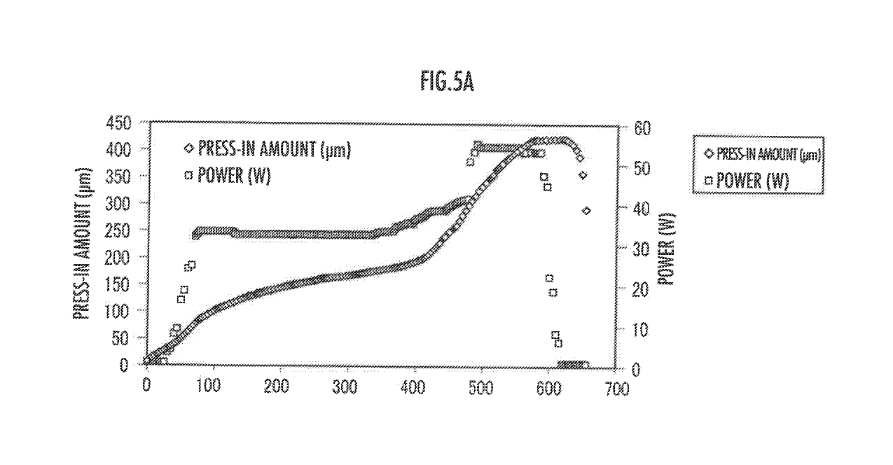

To ultrasonically bond the FFC 2 to the PCB 1, the PCB 1 and the FFC 2 are vertically stacked and held between the horn 41 and the anvil 42, as illustrated in FIG. 3. At this time, each of the upper surface wires 11 of the PCB 1 and each of the external wires 21 of the FFC 2 are vertically stacked through the intermediary of the insulating cover 20 constituting the FFC 2 (refer to FIG. 4). In this state, the horn 41 is displaced toward the anvil 42 by the lift drive device 411 thereby to apply a load in the vertical direction to the PCB 1 and the FFC 2, and a high-frequency AC voltage is applied to the piezoelectric element 412 so as to ultrasonically vibrate the horn 41 (in the horizontal direction or in the lateral direction in the drawing).

The ultrasonic vibration energy of the horn 41 causes a local temperature increase at the places of the PCB 1 and the FFC 2 that are held between the horn 41 and the anvil 42, thus locally melting the insulating cover 20 of the FFC 2. The load in the vertical direction applied by the horn 41 and the anvil 42 causes the molten synthetic resin derived from the insulating cover 20 to be gradually removed from between the horn 41 and the anvil 42. At this time, the insulating cover 20 existing between the upper surface wire 11 and the external wire 21 is also melted and gradually removed from between the upper surface wire 11 and the external wire 21.

In the process of the removal of the molten synthetic resin derived from the insulating cover 20 from between the upper surface wire 11 and the external wire 21, the external wire 21 plastically deforms and comes in contact with the upper surface wires 11. The ultrasonic vibration energy of the horn 41 causes fiction heat to be generated at the place of the contact, and the oxide films generated on the metal surfaces of the upper surface wires 11 and the external wires 21 are removed, causing active surfaces (also referred to as “clean surfaces”) to be exposed and react. Then, after the bonding reaction (also referred to as “solid-phase bonding”) between the upper surface wires 11 and the external wires 21 is completed, the lift drive or the ultrasonic vibration of the horn 41 is stopped. Thus, the PCB 1 and the FFC 2 are bonded at a bonding area X of each of the upper surface wires 11 and the external wires 21 illustrated in FIG. 4.

(Effect)

According to the PCB 1 as an embodiment of the electronic circuit board of the present invention, the second reinforcing members 22 constituting the reinforcing member 12 are bonded to the lower surfaces of the upper surface wires 11, and the second reinforcing members 122 are bonded to the first reinforcing members 121 buried in the substrate 10. With this arrangement, even if the substrate 10 locally incurs a temperature increase and softens due to the ultrasonic vibration energy of the horn 41, the vibration of the upper surface wires 11 will be suppressed by the reinforcing member 12, so that the ultrasonic vibration energy efficiently contributes to the bonding of the contact places of the upper surface wires 11 and the external wires 21. Thus, the bonding quality of the upper surface wires 11 bonded to the upper surface of the PCB 1 and the external wires 21 constituting the FFC 2 is improved.

### WORKING EXAMPLE

According to the embodiment illustrated in FIG. 1 and FIG. 2, an electronic circuit board (PCB 1) of a working example was fabricated. More specifically, an upper surface wire 11 shaped like a substantially square-shaped plate which is made of copper and which measures 3 [mm]×3 [mm] and 70 [μm] thick was bonded onto a substrate 10 made of an epoxy glass resin. Second reinforcing members 122, each of which has a 0.5-mm diameter and has a substantially columnar shape, were bonded to the four corners of the lower surface of the upper surface wire 11. The second reinforcing members 122 are arranged to connect the upper surface wire 11, two first reinforcing members 121 vertically set apart, and a lower surface wire 114, as described above.

### COMPARATIVE EXAMPLES

An electronic circuit board of a first comparative example was fabricated in the same manner as that of the working example except that the reinforcing member 12 was omitted, meaning that all the first reinforcing members 121 and the second reinforcing members 122, which are the constituent elements of the reinforcing member 12, were omitted. An electronic circuit board of a second comparative example was fabricated in the same manner as that of the working example except that all the second reinforcing members 122, which are the constituent elements of the reinforcing member 12, were omitted.

(Evaluation)

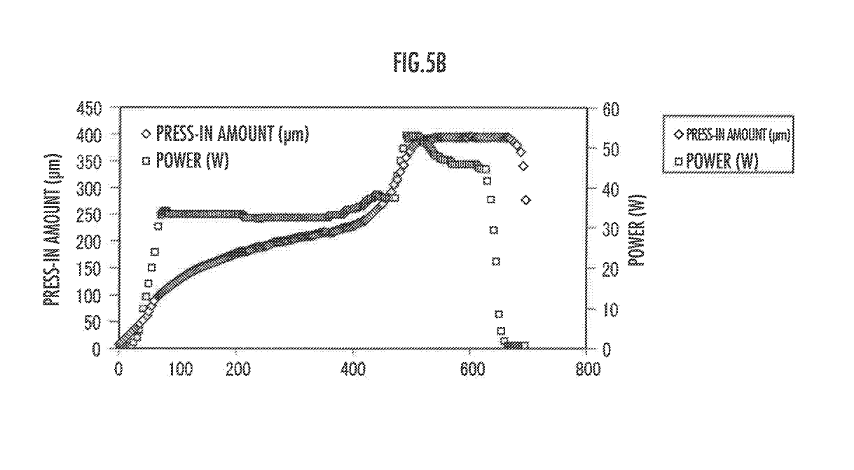

An FFC 2 was bonded to the electronic circuit board of each of the working example, the first comparative example and the second comparative example. FIG. 5A and FIG. 5B illustrate the temporal changes in the displacement amount (the press-in amount) of a horn 41 and in the ultrasonic vibration power thereof when the electronic circuit board of each of the working example and the second comparative example are subjected to bonding. The power (the product of a voltage and a current) applied to the horn 41 by a piezoelectric element is defined as the ultrasonic vibration power.

After the horn 41 comes in contact with the FFC 2, the displacement amount slowly increases, and the temperature of an insulating cover 20 of the FFC 2 gradually increases in the process in which the ultrasonic vibration power is maintained substantially constant. As the melting of the insulating cover 20 and the removal thereof from between the horn 41 and an anvil 42 proceeds, the displacement amount of the horn 41 increases more rapidly than before and the ultrasonic vibration energy increases. Thereafter, when an upper surface wire 11 and an external wire 21 come in contact with each other, the bonding between the conductors begins, and the ultrasonic vibration power (amplitude) increases. Thereafter, the amplitude of the AC voltage applied to a piezoelectric element 412 is controlled by a controller 40 such that the amplitude is maintained constant according to the local softening of a synthetic resin constituting a substrate 10 in addition to the local bonding of a metal constituting the upper surface wire 11 and a metal constituting the external wire 21. Then, upon the completion of the bonding, the supply of the ultrasonic energy is stopped.

It is seen from FIG. 5A and FIG. 5B that, before and after the displacement amount of the horn 41 is maintained substantially constant according to the contact between the upper surface wire 11 and the external wire 21, the maximum value of the ultrasonic vibration power is larger in the working example than in the second example 2. Further, it is seen that the period of time during which the ultrasonic vibration power is maintained substantially constant in the vicinity of the maximum value is longer in the working example than in the second example. This indicates that the frictional force applied to the horn 41 from the place where the horn 41 comes in contact with the external wire 21 due to the contact between the upper surface wire 11 and the external wire 21 is larger and lasts longer in the working example than in the second comparative example, meaning that the vibration of the upper surface wire 11 is suppressed by the reinforcing member 12.

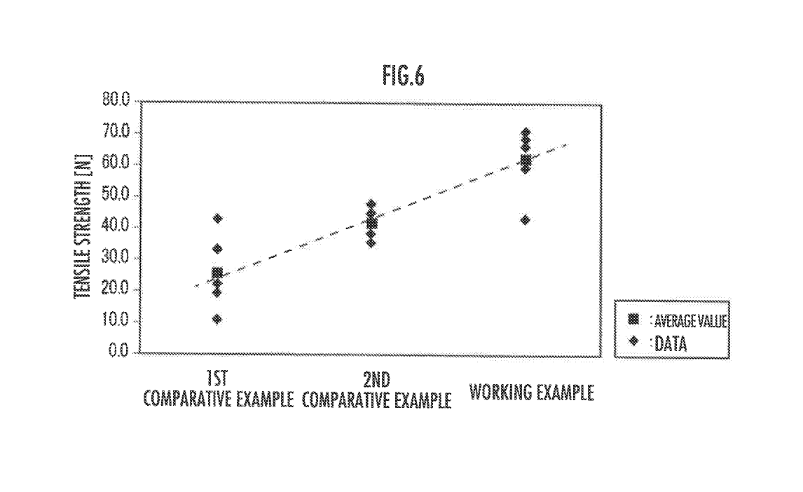

FIG. 6 illustrates the results of evaluation of the bonding strengths of the upper surface wire 11 and the external wire 21, which have been bonded as described above. To measure the bonding strength, first, in a state in which the upper surface wires 11 bonded to the upper surface of the PCB 1 and the external wire 21 constituting the FFC 2 had been solid-phase bonded by the ultrasonic vibration energy, these conductors are mounted on a PCB holding section configured under a tensile testing device such that the FFC 2 is perpendicular to the tensile testing device. Then, the FFC 2 is set on a lead wire fixing section provided on the drive section of the tensile testing device such that no tensile stress is generated in the FFC 2. From this state, the FFC 2 is pulled up in the vertical direction at a speed of 20 [mm/min]. The tensile strength of the external wire 22 with respect to the upper surface wires 11, which is measured according to the method described above, was measured as the bonding strength. From FIG. 6, it is seen that the bonding strength is higher in the working example than in the first and the second comparative examples.

### Other Embodiments of the Present Invention

In the foregoing embodiment, the first reinforcing members 121, which are the constituent elements of the reinforcing member 12, are buried in the substrate 10. As another embodiment, however, the first reinforcing members 121 may alternatively be bonded to the upper surface or the lower surface of the substrate 10. In the case where the first reinforcing members 121, which have a substantially tabular shape, are bonded to the upper surface of the substrate 10, for example, the end portions of the second reinforcing members 122, which have a bent or curved shape and which are extended downward and extended being bent in the horizontal direction and then extended being bent upward may be bonded to the lower surfaces of the upper surface wires 11 and the first reinforcing members 121. In the case where the first reinforcing members 121, which have the substantially tabular shape, are bonded to the lower surface of the substrate 10, for example, the end portions of the second reinforcing members 122, which have a substantially columnar shape extending in the vertical direction, may be bonded to the lower surfaces of the upper surface wires 11 and the upper surfaces of the first reinforcing members 121.

In the foregoing embodiment, the second reinforcing members 122 serve as the vias of the upper surface wires 11 and the lower surface wires 114. However, as another embodiment, the second reinforcing members 122 may be provided separately from the vias of the upper surface wires 11 and the lower surface wires 114. The reinforcing member 12 has been bonded to additional wires (the lower surface wires 114 in the foregoing embodiment) in addition to the upper surface wires 11, which are to be bonded. Alternatively, however, the reinforcing member 12 may be bonded only to the upper surface wires 11, which are to be bonded, among a plurality of wires constituting the PCB 1 (the electronic circuit board). Further alternatively, the first reinforcing members 121 may be constituted of some of the internal wires.

### DESCRIPTION OF REFERENCE NUMERALS

1 . . . PCB (Electronic circuit board); 2 . . . FFC; 10 . . . Substrate; 11 . . . Upper surface wire (a conductor); 12 . . . Reinforcing member; 121 . . . First reinforcing member; 122 . . . Second reinforcing member; 20 . . . Insulating cover; 21 . . . External wire (another conductor); 4 . . . Ultrasonic bonding apparatus; 40 . . . Controller; 41 . . . Horn; 42 . . . Anvil; 411 . . . Lift drive device; and 412 . . . Piezoelectric element (Ultrasonic vibrator).

1. An electronic circuit board comprising: a substrate which includes a synthetic resin; and a conductor bonded to an upper surface of the substrate,
wherein a reinforcing member made of a material having a melting point that is higher than that of the substrate is bonded to a lower surface of the conductor such that the reinforcing member does not affect a conduction state between the conductor and a wiring of the electronic circuit board, and buried in the substrate or bonded to a lower surface or the upper surface of the substrate.

2. The electronic circuit board according to claim 1,
wherein the reinforcing member includes one or a plurality of tabular first reinforcing members, which are disposed apart downward with respect to the conductor, and a second reinforcing member which vertically connects the substrate and the first reinforcing member or members.

3. A method for ultrasonically bonding another conductor to the conductor bonded to the upper surface of the electronic circuit board according to claim 1, the method comprising:
a step of sandwiching, by a horn vibrated by a piezoelectric element and an anvil disposed opposing the horn, the electronic circuit board and the another conductor such that an exposed place of the upper surface of the conductor and the another conductor vertically overlap; and
a step of displacing the horn downward while ultrasonically vibrating the horn in a horizontal direction so as to bond the conductor, which is disposed on the electronic circuit board, and the another conductor.
